(19) United States
(12) Patent Application Publication
(10) Pub. No.: US 2003/0158689 A1
(43) Pub. Date: Aug. 21, 2003

(54) Method for extracting parasitic capacitances of field-effect transistors

(76) Inventors: Yeong-Lin Lai, Shindian City (TW); Cheng-Tsung Chen, Taichung (TW)

Correspondence Address: MICHAEL BEST & FRIEDRICH LLC, 401 NORTH MICHIGAN AVENUE, SUITE 1700, CHICAGO, IL, 60611-4212, US

(21) Appl. No.: 10/300,085

(22) Filed: Nov. 20, 2002

(30) Foreign Application Priority Data
Nov. 20, 2001 (TW) 90128766

(51) Int. Cl. G01R 15/00; G06F 19/00; G01R 27/28; G01R 31/00; G01R 31/14

(52) U.S. Cl. 702/120

(57) ABSTRACT

The purpose of the present invention is to provide a method to extract the extrinsic capacitances of FETs by a physically-meaningful capacitive transmission line model and a linear regression technique. The method of the present invention includes method includes steps of (a) applying a gate-to-source voltage to pinch-off said FETs and setting a drain-to-source voltage to be zero for forming pinched-off cold FETs, (b) measuring S-parameters of said pinched-off cold FETs, (c) representing an intrinsic depletion region of said pinched-off cold FETs by a distributed capacitive transmission line model having a distributed series capacitance Cₛ and a distributed parallel capacitance Cₚ; and (d) executing an analytical procedure according to said measured S-parameters for obtaining Y-parameters.

### FIELD OF THE INVENTION

The present invention is related to a parameter extraction method, and more particularly, to a parameter extraction method for extracting parasitic capacitances of field-effect transistors.

### BACKGROUND OF THE INVENTION

The small-signal equivalent-circuit model plays an important role for evaluation of microwave performance of field-effect transistors (FETs) and design of monolithic microwave integrated circuits (MMICs). The accurate extrinsic capacitance parameters are essential for determination of the small-signal equivalent circuit model. The pinched-off cold-FET methods, in which the gate-to-source voltage (V_{GS}) was applied to turn an FET off and the drain-to-source voltage (V_{DS}) was set to zero, have been widely studied to extract the extrinsic capacitance parameters of the FETs such as metal-semiconductor field-effect transistors (MESFETs), heterojunction field-effect transistors (HFETs), and high-electron-mobility transistors (HEMTs). These pinched-off cold-FET methods reported use lumped capacitance model to describe the intrinsic depletion region under the gate. The extrinsic gate capacitance (C_{pg}) and drain capacitance (C_{pd}) can be determined from the Y-parameter frequency response of the devices. On the other hand, the distributed capacitance model has been used to represent the intrinsic depletion region under the gate for the pinched-off cold FET to extract the C_{pg} and the C_{pd}. The length of the depletion region was assumed to be linearly dependent on the gate bias. However, the assumption can not be applied to the common FETs with a uniformly-doped channel.

Therefore, it is tried to rectify those drawbacks and provide a parameter extraction method for field-effect transistors by the present applicant.

### SUMMARY OF THE INVENTION

It is an object of the present invention to provide an accurate, fast, and simple method for extracting the extrinsic capacitances of FETs by a physically-meaningful capacitive transmission line model and a linear regression technique.

The object of the present invention described above is achieved by a pinched-off cold-FET method using a capacitive transmission line model to extract extrinsic capacitances for the small-signal equivalent circuit of FETs with a gate, a drain, and a source, comprising the steps of:

(a) applying the gate-to-source voltage to pinch-off FETs and setting the drain-to-source voltage to be zero to obtain the pinched-off cold FETs;

(b) measuring the S-parameters of the piched-off cold FETs;

(c) representing the intrinsic depletion region of the pinched-off cold FETs by the distributed capacitive transmission line model with the distributed series capacitance (Cₛ) and the distributed parallel capacitance (Cₚ) and extracting the extrinsic gate capacitance C_{pg} and drain capacitance C_{pd} of the FETs by the analytical procedures associated with the measured Y-parameters transferred from the measured S-parameters.

According to the pinched-off cold-FET method of the present invention described above, the extrinsic C_{pg} and C_{pd} of the FETs are extracted by the analytical procedures in the step (c), comprising the steps of:

(c1) expressing the imaginary parts of the Y-parameters associated with frequencies by specific equations and find the linear relationship of the imaginary parts of the Y-parameters;

(c2) obtaining the relation equation between the C_{pg} and the C_{pd} according to the linear relationship of the imaginary parts of the Y-parameters; and

(c3) determining the C_{pg} and C_{pd} according to the relation equation between the C_{pg} and the C_{pd} and the specific equations of the imaginary parts of the Y-parameters.

In the present invention, the ABCD matrix of the pinched-off cold FET is indicated by MFET and expressed by

M_{FET}=M_{pg}·M_{CTL}·M_{pd}

The elements of the MFET include

M_{FET11}=cos h(γl)+Y_{pd}Z₀ sin h(γl)

M_{FET12}=Z₀ sin h(γl)

$${M}_{FET 21} = ( {Y}_{pg} + {Y}_{pd} ) cosh ( γ l ) + ( \frac{1}{{Z}_{0}} + {Y}_{pg} {Y}_{pd} {Z}_{0} ) sinh ( γ l )$$

M_{FET22}=cos h(γl)+Y_{pg}Z₀ sin h(γl)

where γ is the propagation constant, l is the length of the transmission line, and the Z₀ is the characteristic impedance;

$$\begin{matrix}γ = \sqrt{\frac{{C}_{p}}{{C}_{s}}} \\ {Z}_{0} = \frac{1}{j ω \sqrt{{C}_{p} {C}_{s}}}\end{matrix}$$

From the plot of the measurement characteristics of the Im(Y₂₂)/ω versus the Im(Y₁₁)/ω, the linear relationship between Im(Y₂₂)/ω and Im(Y₁₁)/ω is found. The slope of the Im(Y₂₂)/ω versus the Im(Y₁₁)/ω can be obtained by the linear regression technique. The relation equation between the C_{pg} and the C_{pd} is then obtained.

In the present invention, the specific equations expressing the imaginary parts of the Y-parameters associated with frequencies are derived as follows:

$$\begin{matrix}\frac{Im ( {Y}_{FET 11} )}{ω} = {C}_{pg} + \frac{\sqrt{{C}_{p} {C}_{s}}}{tanh ( γ l )} \\ \frac{Im ( {Y}_{FET 22} )}{ω} = {C}_{pd} + \frac{\sqrt{{C}_{p} {C}_{s}}}{tanh ( γ l )}\end{matrix}$$

where C_{pg} is the extrinsic gate capacitance and C_{pd} is the extrinsic drain capacitance.

Accordingly, the relation equation between the C_{pg} and the C_{pd} is:

$$\begin{matrix}\frac{Im ( {Y}_{22} ) / ω}{Im ( {Y}_{11} ) / ω} = \frac{{C}_{pd} + C}{{C}_{pg} + C} \\ C = \frac{\sqrt{{C}_{p} {C}_{s}}}{tanh ( γ l )}\end{matrix}$$

where the constant C is related with the device parameters under a fixed bias condition.

Certainly, the materials and structures of the FETs can be any possible materials and structures of the MESFETs.

Certainly, the materials and structures of the FETs can be any possible materials and structures of the HFETs.

Certainly, the materials and structures of the FETs can be any possible materials and structures of the HEMTs.

Preferably, the substrate materials of the FETs is GaAs, InP, GaN, or any possible compound semiconductor materials.

Preferably, the FETs is either n-channel FETs or p-channel FETs.

Preferably, the measurement frequencies are the normal operation frequencies of the FETs.

Certainly, the gate length of the FETs can be sub-micron, deep sub-micron, nano-meter, and any possible dimension to make the FETs operate.

Certainly, the gate voltage of the pinched-off cold FETs can be any possible voltage to make the FETs pinch-off.

Certainly, the measurement instruments of the S-parameters of the pinched-off cold FETs can be any type of network analyzers and instruments.

Furthermore, the object of the present invention is also to provide a method for building up the small-signal equivalent circuit of FETs with a gate, a drain, and a source, comprising the steps of:

(a) applying the gate-to-source voltage to pinch-off FETs and setting the drain-to-source voltage to be zero to obtain the pinched-off cold FETs;

(b) measuring the S-parameters of the FETs;

(c) representing the intrinsic depletion region of the pinched-off cold FETs by the distributed capacitive transmission line model with the distributed series capacitance Cₛ and the distributed parallel capacitance Cₚ and extracting the extrinsic gate capacitance C_{pg} and drain capacitance C_{pd} of the FETs by the analytical procedures associated with the measured Y-parameters transferred from the measured S-parameters; and

(d) building up the small-signal equivalent circuit of FETs by the extracted C_{pg} and C_{pd}.

The foregoing and other features and advantages of the present invention will be more clearly understood through the following descriptions with reference to the drawings, wherein:

### BRIEF DESCRIPTION OF THE DRAWING

FIG. 1 shows a small-signal equivalent circuit of MESFETs and HEMTs;

FIG. 2 shows a small-signal equivalent circuit at the pinched-off cold-FET condition;

FIG. 3 shows a small-signal equivalent-circuit model of the pinched-off cold FET represented by the M_{CTL} in conjunction with the M_{pg} and the M_{pd}, wherein the extrinsic resistances and inductances are ignored;

FIG. 4 shows the plot of the measurement characteristics of the Im(Y₂₂)/ω versus the Im(Y₁₁)/ω;

FIG. 5 shows a smith chart of S-parameters for S₁₁ and S₂₂, wherein the symbol ‘+’ indicates the measured S₁₁, the symbol ‘⋄’ indicates the measured S₂₂, and the simulated S-parameters are indicated by solid lines; and

FIG. 6 shows a polar plot of S-parameters for S₁₂ and S₂₁, wherein the symbol ‘+’ indicates the measured S₁₂, the symbol ‘⋄’ indicates the measured S₂₁, and the simulated S-parameters are indicated by solid lines.

### DETAILED DESCRIPTION OF THE PREFERRED EMBODIMENTS

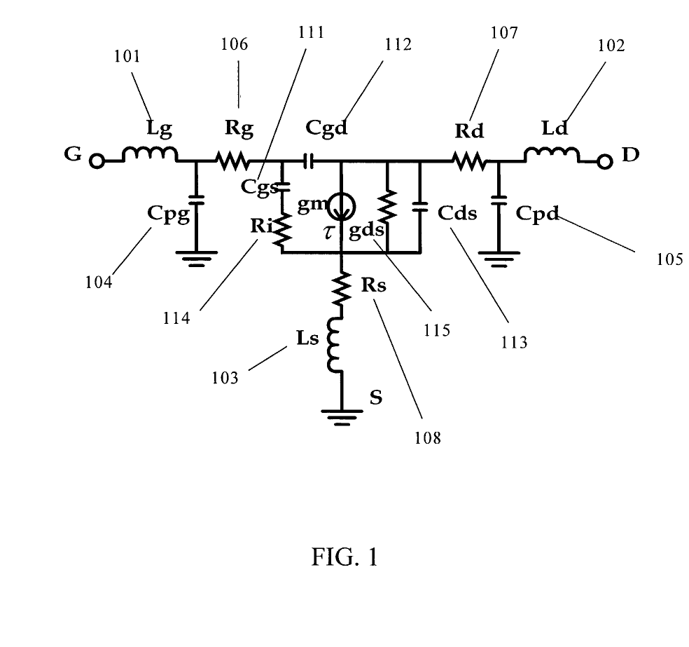

FIG. 1 shows a small-signal equivalent circuit of MESFETs and HEMTs. The proposed equivalent circuit of MESFETs and HEMTs is composed of two parts, the intrinsic elements and the extrinsic elements. The extrinsic elements, L_{g} 101, L_{d} 102, Lₛ 103, C_{pg} 104, C_{pd} 105, R_{g} 106, R_{d} 107, and Rₛ 108, defined as the extrinsic parameters, are bias-independent. And the intrinsic elements, C_{gs} 111, C_{gd} 112, C_{ds} 113, Rᵢ 114, gds 115, gm, and τ, defined as the intrinsic parameters, are associated with the variation of the bias. By reason of few equations to extract the parameters of the whole equivalent circuit, we have to utilize the pinched-off (V_{GS}<Vₚ) cold-FET (V_{DS}=0) condition to simplify the intrinsic part.

The symmetric depletion region of the pinched-off cold FETs can be represented by the distributed capacitive transmission line model that consists of two different kinds of capacitances, Cₛ 202 and Cₚ 201.

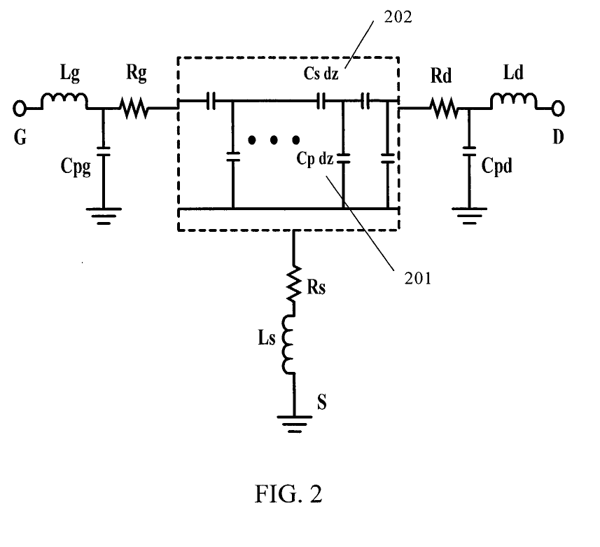

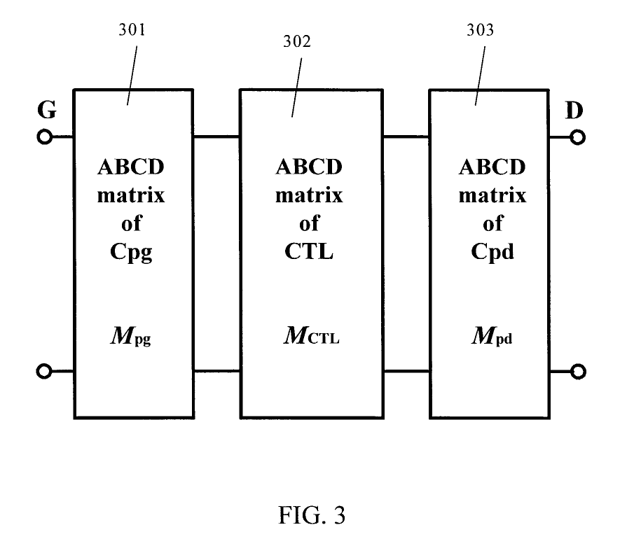

FIG. 2 shows a small-signal equivalent circuit at the pinched-off cold-FET condition. The small-signal equivalent-circuit model of the pinched-off cold FET can be represented by the Y parameters. The imaginary parts of the Y parameters are not influenced by the extrinsic resistances (R_{g}, R_{d}, and Rₛ) and the extrinsic inductances (L_{g}, L_{d}, and Lₛ) at the frequencies up to a few GHz. After ignoring the extrinsic resistances and inductances, the small-signal equivalent-circuit model of the pinched-off cold FET is described by the M_{CTL} matrix 302 in conjunction with the M_{pg} 301 and the M_{pd} 303 for the C_{pg} and the C_{pd} as shown in FIG. 3. And then on the basis of the fundamental transmission line theory, we can obtain the ABCD matrix of the distributed capacitive transmission line.

The ABCD matrix of the pinched-off cold FET is indicated by MFET and expressed by

M_{FET}=M_{pg}·M_{CTL}·M_{Pd}

The elements of the MFET include

M_{FET11}=cos h(γl)+Y_{pd}Z₀ sin h(γl)

M_{FET}₁₂=Z₀ sin h(γl)

$${M}_{FET 21} = ( {Y}_{pg} + {Y}_{pd} ) cosh ( γ l ) + ( \frac{1}{{Z}_{0}} + {Y}_{pg} {Y}_{pd} {Z}_{0} ) sinh ( γ l )$$

M_{FET22}=cos h(γl)+Y_{pg}Z₀ sin h(γl)

where γ is the propagation constant, l is the length of the transmission line, and the Z₀ is the characteristic impedance;

$$\begin{matrix}γ = \sqrt{\frac{{C}_{p}}{{C}_{s}}} \\ {Z}_{0} = \frac{1}{j ω \sqrt{{C}_{p} {C}_{s}}}\end{matrix}$$

By the relation between ABCD-parameters and Y-parameters, we can convert the ABCD matrix into Y parameters. The specific equations expressing the imaginary parts of the Y-parameters associated with frequencies are derived as follows:

$$\begin{matrix}\frac{Im ( {Y}_{FET 11} )}{ω} = {C}_{pg} + \frac{\sqrt{{C}_{p} {C}_{s}}}{tanh ( γ l )} \\ \frac{Im ( {Y}_{FET 22} )}{ω} = {C}_{pd} + \frac{\sqrt{{C}_{p} {C}_{s}}}{tanh ( γ l )}\end{matrix}$$

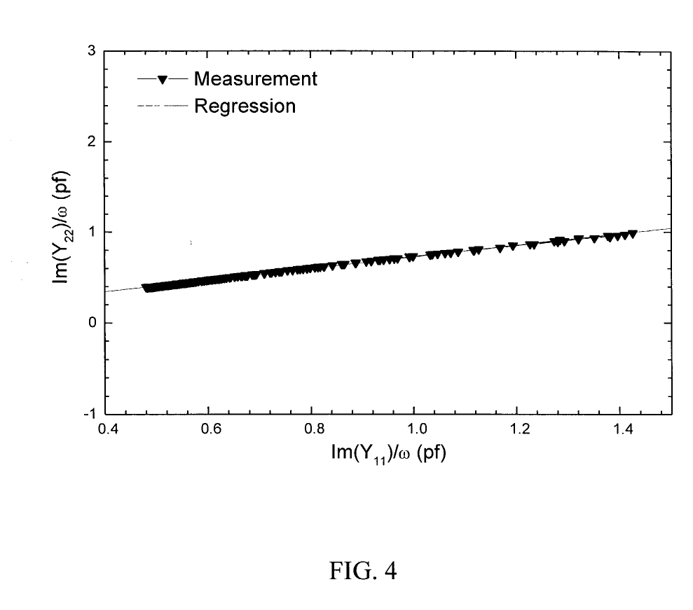

FIG. 4 shows the plot of the measurement characteristics of the Im(Y₂₂)/ω versus the Im(Y₁₁)/ω. According to FIG. 4, the slope of the Im(Y₂₂)/ω versus the Im(Y₁₁)/ω can be obtained by the linear regression technique. The relation equation between the C_{pg} and the C_{pd} is then obtained.

$$\begin{matrix}\frac{Im ( {Y}_{22} ) / ω}{Im ( {Y}_{11} ) / ω} = \frac{{C}_{pd} + C}{{C}_{pg} + C} \\ C = \frac{\sqrt{{C}_{p} {C}_{s}}}{tanh ( γ l )}\end{matrix}$$

where C_{pg} is the extrinsic gate capacitance, C_{pd} is the extrinsic drain capacitance and the constant C is related with the device parameters under a fixed bias condition.

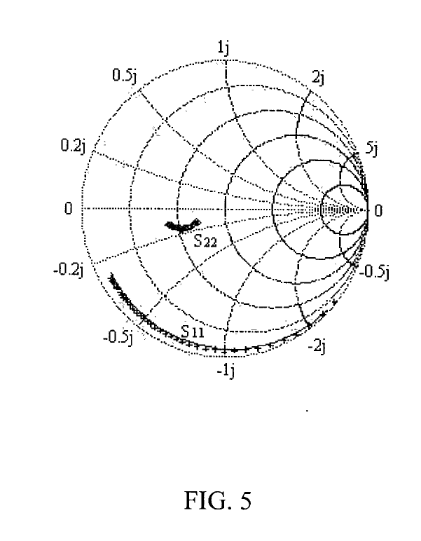

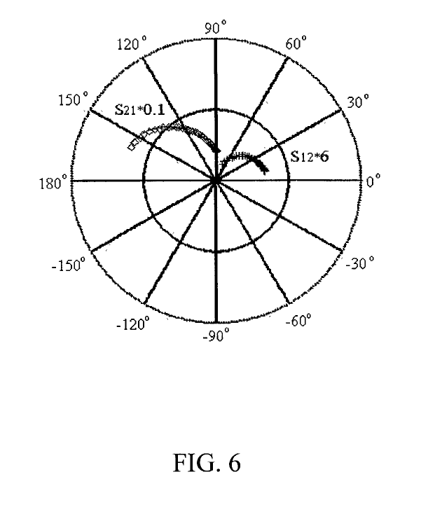

FIG. 5 shows a smith chart of S-parameters for S₁₁ and S₂₂. FIG. 6 shows a polar plot of S-parameters for S₁₂ and S₂₁. As shown in FIG. 5 and FIG. 6, the small-signal equivalent circuit model of the MESFET built shows a great agreement between the simulated and measured S-parameters. The capacitive transmission line model and analytical method demonstrate accurate results for the small-signal equivalent circuit.

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A method for extracting extrinsic capacitances for FETs, wherein each said FET has a gate, a drain, and a source, comprising steps of:
(a) applying a gate-to-source voltage to pinch-off said FETs and setting a drain-to-source voltage to be zero for forming pinched-off cold FETs;
(b) measuring S-parameters of said pinched-off cold FETs;
(c) representing an intrinsic depletion region of said pinched-off cold FETs by a distributed capacitive transmission line model having a distributed series capacitance Cₛ and a distributed parallel capacitance Cₚ; and
(d) executing an analytical procedure according to said measured S-parameters for obtaining Y-parameters.

2. The method as claimed in claim 1, wherein said analytical procedure in the step (d) further comprises steps of:
(d1) associating imaginary parts of said Y-parameters with frequencies by a specific equation for obtaining a linear relationship of said imaginary parts of said Y-parameters;
(d2) obtaining a relation equation between an extrinsic gate capacitance C_{pg} and an extrinsic drain capacitance C_{pd} according to said linear relationship of said imaginary parts of said Y-parameters; and
(d3) determining said C_{pg} and said C_{pd} according to said relation equation between said C_{pg} and said C_{pd} and said specific equations of said imaginary parts of the Y-parameters.

3. The method as claimed in claim 2, wherein said step (d1) further comprises steps of:
(e1) providing a matrix M_{FET} for expressing said pinched-off cold FETs, wherein
M_{FET}=M_{pg}·M_{CTL}·M_{pd}
and elements of said M_{FET} include
M_{FET11}=cos h(γl)+Y_{pd}Z₀ sin h(γl)
M_{FET12}=Z₀ sin h_{(γ}l)
$${M}_{FET 21} = ( {Y}_{pg} + {Y}_{pd} ) cosh ( γ l ) + ( \frac{1}{{Z}_{0}} + {Y}_{pg} {Y}_{pd} {Z}_{0} ) sinh ( γ l )$$
M_{FET22}=cos h(γl)+Y_{pg}Z₀ sin h(γl)
wherein γ is a propagation constant, l is a length of a transmission line, and Z₀ is a characteristic impedance where
$$\begin{matrix}γ = \sqrt{\frac{{C}_{p}}{{C}_{s}}} \\ {Z}_{0} = \frac{1}{j ω \sqrt{{C}_{p} {C}_{s}}} ;\end{matrix}$$
(e2) expressing said imaginary parts of said Y-parameters associated with frequencies by the following equations:
$$\begin{matrix}\frac{Im ( {Y}_{FET11} )}{ω} = {C}_{pg} + \frac{\sqrt{{C}_{p} {C}_{s}}}{tanh ( γ l )} , and \\ \frac{Im ( {Y}_{FET22} )}{ω} = {C}_{pd} + \frac{\sqrt{{C}_{p} {C}_{s}}}{tanh ( γ l )} ; and\end{matrix}$$
(e3) forming a plot of measurement characteristics of said Im(Y₂₂)/ω versus said Im(Y₁₁)/ω, for obtaining a linear relationship between Im(Y₂₂)/ω and Im(Y₁₁)/ω thereby said relation equation between said C_{pg} and said C_{pd} being then obtained.

4. The method as claimed in claim 3, wherein a slope of said Im(Y₂₂)/ω versus said Im(Y₁₁)/ω is obtained by a linear regression technique.

5. The method as claimed in claim 2, wherein said relation equation between said C_{pg} and said C_{pd} includes:
$$\begin{matrix}\frac{Im ( {Y}_{22} ) / ω}{Im ( {Y}_{11} ) / ω} = \frac{{C}_{pd} + C}{{C}_{pg} + C} , and \\ C = \frac{\sqrt{{C}_{p} {C}_{s}}}{tanh ( γ l )}\end{matrix}$$
wherein C_{pg} is said extrinsic gate capacitance, C_{pd} is said extrinsic drain capacitance and constant C is related with a device parameters under a fixed bias condition.

6. The method as claimed in claim 2, wherein said frequencies are normal operation frequencies of said FETs.

7. The method as claimed in claim 1, wherein said FETs are MESFETs.

8. The method as claimed in claim 1, wherein said FETs are HFETs.

9. The method as claimed in claim 1, wherein said FETs are HEMTs.

10. The method as claimed in claim 1, wherein said FETs arc selected from a group consisting of a GaAs, an InP, a GaN semiconductors.

11. The method as claimed in claim 1, wherein said FETs are one of n-channel FETs and p-channel FETs.

12. The method as claimed in claim 1, wherein said gate length dimension of said FETs is one selected from a group consisting of sub-micron, deep sub-micron, and nano-meter.

13. The method as claimed in claim 1, wherein said S-parameters of said pinched-off cold FETs are measured by network analyzers and instruments.

14. A method for FETs to build up a small-signal equivalent circuit, wherein each said FETs has a gate, a drain, and a source, comprising steps of:
(a) applying a gate-to-source voltage to pinch-off said FETs and setting a drain-to-source voltage to be zero for obtaining pinched-off cold FETs;
(b) measuring S-parameters of said piched-off cold FETs FETs;
(c) representing an intrinsic depletion region of said pinched-off cold FETs by a distributed capacitive transmission line model having a distributed series capacitance Cₛ and a distributed parallel capacitance Cₚ;
(d) executing an analytical procedure according to said measured S-parameters for obtaining a relation equation of an extrinsic gate capacitance C_{pg} and an extrinsic drain capacitance C_{pd}; and
(e) building up said small-signal equivalent circuit of said FETs by said relation equation of said extrinsic gate capacitance C_{pg} and said extrinsic drain capacitance C_{pd}.

15. The method as claimed in claim 14, wherein said analytical procedure in the step (d) further comprises steps of:
(d1) associating imaginary parts of said Y-parameters with frequencies by a specific equation for obtaining a linear relationship of said imaginary parts of said Y-parameters;
(d2) obtaining a relation equation between an extrinsic gate capacitance C_{pg} and an extrinsic drain capacitance C_{pd} according to said linear relationship of said imaginary parts of said Y-parameters; and
(d3) determining said C_{pg} and said C_{pd} according to said relation equation between said C_{pg} and said C_{pd} and said specific equations of said imaginary parts of the Y-parameters.

16. The method as claimed in claim 15, wherein said step (d1) further comprises steps of:
(f1) providing a matrix MFET for expressing said pinched-off cold FETs, wherein
M_{FET}=M_{pg}·M_{CTL}·M_{pd}
and elements of said MFET include
M_{FET11}=cos h(γl)+Y_{pd}Z₀ sin h(γl)
M_{FET}₁₂=Z₀ sin h(γl)
$${M}_{FET21} = ( {Y}_{pg} + {Y}_{pd} ) cosh ( γ l ) + ( \frac{1}{{Z}_{0}} + {Y}_{pg} {Y}_{pd} {Z}_{0} ) sinh ( γ l )$$
M_{FET}₂₂=cos h(γl)+Y_{pg}Z₀ sin h(γl)
wherein γ is a propagation constant, l is a length of a transmission line, and Z₀ is a characteristic impedance where
$$\begin{matrix}γ = \sqrt{\frac{{C}_{p}}{{C}_{s}}} \\ {Z}_{0} = \frac{1}{j ω \sqrt{{C}_{p} {C}_{s}}} ;\end{matrix}$$
(f2) expressing said imaginary parts of said Y-parameters associated with frequencies by the following equations:
$$\begin{matrix}\frac{Im ( {Y}_{FET11} )}{ω} = {C}_{pg} + \frac{\sqrt{{C}_{p} {C}_{s}}}{tanh ( γ l )} , and \\ \frac{Im ( {Y}_{FET22} )}{ω} = {C}_{pd} + \frac{\sqrt{{C}_{p} {C}_{s}}}{tanh ( γ l )} ; and\end{matrix}$$
(f3) forming a plot of measurement characteristics of said Im(Y₂₂)/ω versus said Im(Y₁₁)/ω, for obtaining a linear relationship between Im(Y₂₂)/ω and Im(Y₁₁)/ω thereby said relation equation between said C_{pg} and said C_{pd} being then obtained.

17. The method as claimed in claim 16, wherein a slope of said Im(Y22)/ω versus said Im(Y11)/ω is obtained by a linear regression technique.

18. The method as claimed in claim 15, wherein said relation equation between said C_{pg} and said C_{pd} includes:
$$\begin{matrix}\frac{Im ( {Y}_{22} ) / ω}{Im ( {Y}_{11} ) / ω} = \frac{{C}_{pd} + C}{{C}_{pg} + C} , and \\ C = \frac{\sqrt{{C}_{p} {C}_{s}}}{tanh ( γ l )}\end{matrix}$$
wherein C_{pg} is said extrinsic gate capacitance, C_{pd} is said extrinsic drain capacitance and constant C is related with a device parameters under a fixed bias condition.
